(19) United States
(12) Patent Application Publication
(10) Pub. No.: US 2026/0149235 A1
(43) Pub. Date: May 28, 2026

(54) METHOD FOR MANUFACTURING SEMICONDUCTOR DEVICE

(71) Applicant: Mitsubishi Electric Corporation, Tokyo (JP)

(72) Inventor: Takahiro UENO, Tokyo (JP)

(73) Assignee: Mitsubishi Electric Corporation, Tokyo (JP)

(21) Appl. No.: 19/121,995

(22) PCT Filed: Feb. 14, 2023
(86) PCT No.: PCT/JP2023/004900

§ 371 Date: Apr. 17, 2025

(51) Int. Cl. H01S 5/042; H01S 5/227

(52) U.S. Cl. CPC H01S 5/0425; H01S 5/227

(57) ABSTRACT

A method for manufacturing a semiconductor device includes: a step of forming a mesa (16) on a semiconductor substrate (12); a step of forming a lower layer resist (20) soluble in a developer, to cover the mesa (16); a step of forming an upper layer resist (22) to cover the lower layer resist (20); a step of forming a sensitised portion (26) by sensitising a region of the upper layer resist (22) covering the mesa (16); a step of removing the sensitised portion (26) and a part of the lower layer resist (20) by using the developer, and forming a metal layer (18) on the mesa (16); and a step of removing the upper layer resist (22) and the lower layer resist (20).

### FIELD

The present disclosure relates to a method for manufacturing a semiconductor device.

### BACKGROUND

Some of semiconductor devices include mesas. For example, in a semiconductor laser, a mesa including an active layer is provided. In the semiconductor device including the mesa, an electrode metal layer is formed on the mesa in order to energize an active element and the like positioned inside or near the mesa. PTL 1 discloses a method for manufacturing a semiconductor device in which an electrode is provided on a mesa.

In a semiconductor laser used for an optical communication network or a datacenter, it is necessary to reduce a width of the mesa in order to perform high-speed operation. In a case where the width of the mesa is not reduced, a parasitic capacitance is increased. When the parasitic capacitance is increased, a time constant of charging/discharging is increased. Therefore, high-speed operation cannot be realized. Thus, it is necessary to reduce the width of the mesa.

### CITATION LIST

### Patent Literature

[PTL 1] JP H4-320027 A

### SUMMARY

### Technical Problem

However, when the width of the mesa is reduced, dimensional variation of a metal layer provided on the mesa is increased. In a case where the width of the mesa is reduced to a dimension less than or equal to about a resolution of an exposure machine, it is difficult to perform mask alignment with desired accuracy in a manufacturing step. As a result, the metal layer having a desired dimension cannot be formed on the mesa. By the manufacturing method disclosed in PTL 1, the dimensional variation of the metal layer is increased.

The present disclosure has been made to solve the above-described problems, and an object of the present disclosure is to provide a method for manufacturing a semiconductor device that can suppress dimensional variation of a metal layer on a mesa.

### Solution to Problem

The first method for manufacturing a semiconductor device according to the disclosure includes a step of forming a mesa on a front surface of a semiconductor substrate; a step of forming a lower layer resist soluble in a developer, to cover the front surface and the mesa; a step of forming an upper layer resist in which a sensitised region is soluble in a developer, to cover the lower layer resist; a step of forming a sensitised portion by sensitising a region of the upper layer resist covering at least the mesa in a width direction of the mesa as viewed from a direction perpendicular to the front surface; a step of exposing an upper surface of the mesa by removing the sensitised portion and a part of the lower layer resist by using a developer; a step of forming a metal layer on the mesa, on the upper layer resist, and on a region in contact with at least the mesa, of a surface of the lower layer resist exposed in the step of exposing the upper surface of the mesa; and a step of removing portions of the metal layer on the upper layer resist and the lower layer resist, the upper layer resist, and the lower layer resist.

The second method for manufacturing a semiconductor device according to the disclosure includes a step of forming a mesa on a front surface of a semiconductor substrate; a step of forming a lower layer resist soluble in a developer, to cover the front surface and the mesa and to be raised on the mesa; a step of forming an upper layer resist to cover the lower layer resist; a step of exposing a portion of the lower layer resist covering the mesa by etching back the upper layer resist; a step of exposing an upper surface of the mesa by removing, by using the developer, a part of the lower layer resist from a portion exposed in the step of exposing the lower layer resist; a step of forming a metal layer on the mesa, on the upper layer resist, and on the lower layer resist exposed in the step of exposing the upper surface of the mesa; and a step of removing portions of the metal layer on the upper layer resist and the lower layer resist, the upper layer resist, and the lower layer resist.

### Advantageous Effects of Invention

According to the present disclosure, it is possible to provide the method for manufacturing the semiconductor device that can suppress dimensional variation of the metal layer on the mesa.

### BRIEF DESCRIPTION OF DRAWINGS

FIG. 1 is a diagram for explaining the method for manufacturing the semiconductor device according to Embodiment 1.

FIG. 2 is a diagram for explaining the method for manufacturing the semiconductor device according to Embodiment 1.

FIG. 3 is a diagram for explaining the method for manufacturing the semiconductor device according to Embodiment 1.

FIG. 4 is a diagram for explaining the method for manufacturing the semiconductor device according to Embodiment 1.

FIG. 5 is a diagram for explaining the method for manufacturing the semiconductor device according to Embodiment 1.

FIG. 6 is a diagram for explaining the method for manufacturing the semiconductor device according to Embodiment 1.

FIG. 7 is a diagram for explaining the method for manufacturing the semiconductor device according to Embodiment 1.

FIG. 8 is a diagram for explaining the method for manufacturing the semiconductor device according to Embodiment 2.

FIG. 9 is a diagram for explaining the method for manufacturing the semiconductor device according to Embodiment 2.

FIG. 10 is a diagram for explaining the method for manufacturing the semiconductor device according to Embodiment 2.

FIG. 11 is a diagram for explaining the method for manufacturing the semiconductor device according to Embodiment 2.

FIG. 12 is a diagram for explaining the method for manufacturing the semiconductor device according to Embodiment 2.

FIG. 13 is a diagram for explaining the method for manufacturing the semiconductor device according to Embodiment 2.

FIG. 14 is a diagram for explaining the method for manufacturing the semiconductor device according to Embodiment 2.

FIG. 15 is a diagram for explaining the method for manufacturing the semiconductor device according to Embodiment 3.

FIG. 16 is a diagram for explaining the method for manufacturing the semiconductor device according to Embodiment 3.

FIG. 17 is a diagram for explaining the method for manufacturing the semiconductor device according to Embodiment 3.

FIG. 18 is a diagram for explaining the method for manufacturing the semiconductor device according to Embodiment 3.

FIG. 19 is a diagram for explaining the method for manufacturing the semiconductor device according to Embodiment 3.

FIG. 20 is a diagram for explaining the method for manufacturing the semiconductor device according to Embodiment 3.

FIG. 21 is a diagram for explaining the method for manufacturing the semiconductor device according to Embodiment 3.

### DESCRIPTION OF EMBODIMENTS

### Embodiment 1

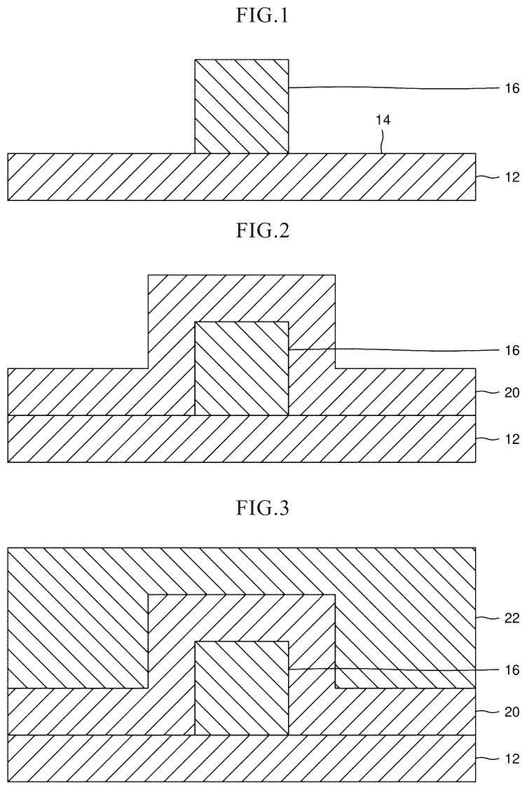

A method for manufacturing a semiconductor device according to Embodiment 1 is described with reference to FIGS. 1 to 7. These figures are cross-sectional views in a direction perpendicular to an extending direction of a mesa 16 having a stripe shape. The semiconductor device is a semiconductor laser, and an active layer generating a laser beam is provided in the mesa 16. A resonance direction of the laser beam is the extending direction of the mesa 16.

First, as illustrated in FIG. 1, the mesa 16 is formed on a front surface 14 of a semiconductor substrate 12. The semiconductor substrate 12 is made of n-type InP. Although not illustrated, the mesa 16 includes a lower clad layer, the active layer, and an upper clad layer that are stacked in order from below. The lower clad layer is made of n-type InP, the active layer is made of InP, and the upper clad layer is made of p-type InP. To form the mesa 16, the lower clad layer, the active layer, and the upper clad layer are stacked in order from below on the front surface 14 of the semiconductor substrate 12. The stacking is performed using an MOCVD (metal organic chemical vapor deposition) method. Thereafter, an insulating film mask having a stripe shape is formed on the upper clad layer, and etching of these three layers is performed using the insulating film mask as a mask, to form the mesa 16. The etching is performed using an ICP (inductively coupled plasma) apparatus. A width direction of the mesa 16 is a direction that is perpendicular to the extending direction of the mesa 16, is parallel to the front surface 14 of the semiconductor substrate 12, and is a right-left direction on a paper surface in FIG. 1. A width of the mesa 16 is 0.1 μm to 10 μm, and a height of the mesa 16 is 1 μm to 10 μm.

Thereafter, as illustrated in FIG. 2, a lower layer resist 20 is formed. The lower layer resist 20 is a resist that does not have photosensitivity and is soluble in a developer. The lower layer resist 20 is formed to cover the front surface 14 of the semiconductor substrate 12 and the mesa 16.

Thereafter, as illustrated in FIG. 3, an upper layer resist 22 is formed. The upper layer resist 22 is a resist that has photosensitivity and in which a sensitised region is soluble in the developer. The upper layer resist 22 is formed to cover the lower layer resist 20. In FIG. 3, a front surface of the upper layer resist 22 is flat, but a portion of the upper layer resist 22 above the mesa 16 may be raised.

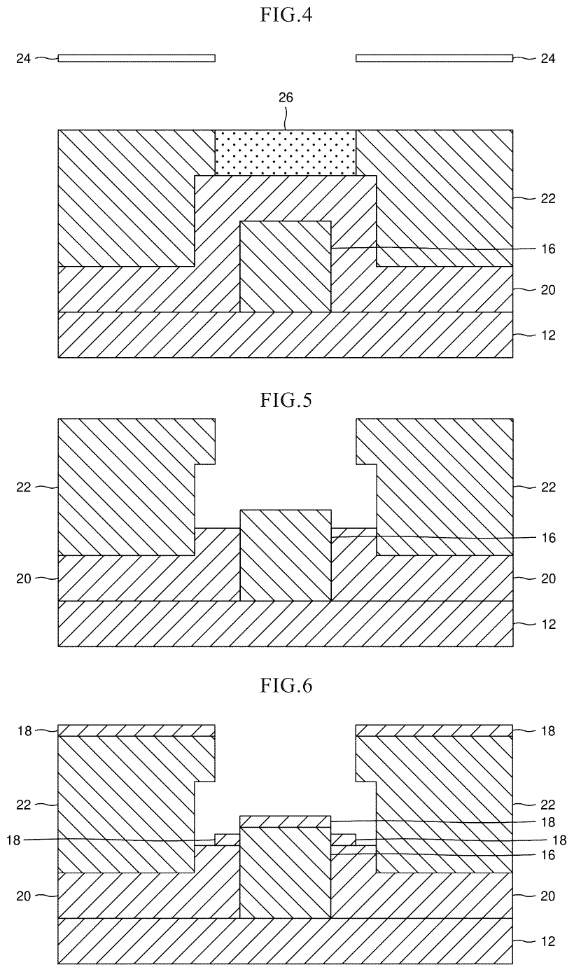

Thereafter, as illustrated in FIG. 4, the upper layer resist 22 above the mesa 16 is sensitised by using a mask 24 having an opening greater than the width of the mesa 16. A region of the upper layer resist 22 covering at least the mesa 16 in the width direction of the mesa 16 as viewed from a direction perpendicular to the front surface 14 of the semiconductor substrate 12 is exposed. The sensitised region is referred to as a sensitised portion 26.

Thereafter, as illustrated in FIG. 5, the sensitised portion 26 and a part of the lower layer resist 20 are removed by using the developer. The sensitised portion 26 is first removed to expose the lower layer resist 20. Subsequently, a part of the lower layer resist 20 is removed from the exposed surface, to expose an upper surface of the mesa 16. At this time, a developing time is adjusted such that an upper end of the lower layer resist 20 beside the mesa 16 is positioned between an upper end of the mesa 16 and a lower end of the mesa 16.

Thereafter, as illustrated in FIG. 6, a metal layer 18 is formed by a vapor deposition method. The metal layer 18 is made of gold, platinum, or the like. The metal layer 18 is formed on the mesa 16, on the upper layer resist 22, and on a region in contact with at least the mesa 16, of a surface of the lower layer resist 20 exposed in the step of exposing the upper surface of the mesa 16. After the metal layer 18 is formed, a side surface of the upper layer resist 22 facing the mesa 16 is exposed. In addition, in a case where the sensitised portion 26 is smaller than the lower layer resist 20 covering the mesa 16 in the width direction of the mesa 16 as viewed from the direction perpendicular to the front surface 14 of the semiconductor substrate 12 as illustrated in FIG. 4, an exposed surface not covered with the metal layer 18 is present on the lower layer resist 20 as illustrated in FIG. 6.

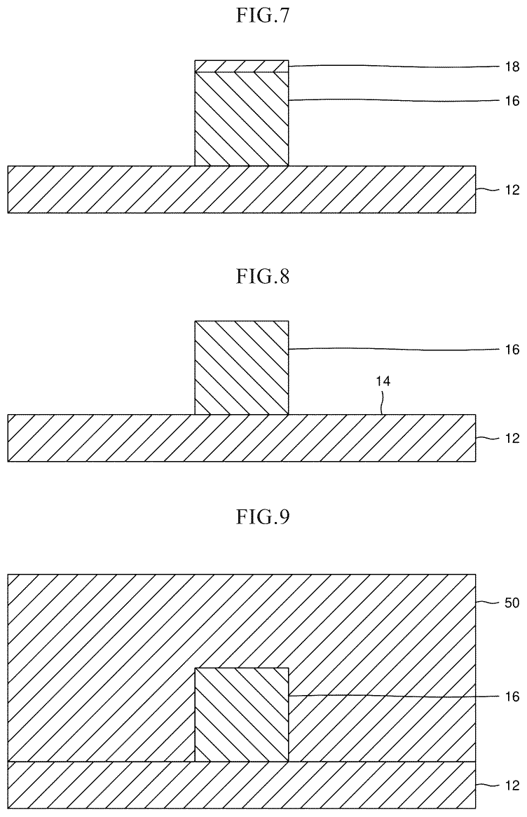

Thereafter, as illustrated in FIG. 7, the upper layer resist 22 and the lower layer resist 20 are removed by liftoff. At the same time, portions of the metal layer 48 on the upper layer resist 52 and the lower layer resist 50 are also removed. A chemical solution used for the liftoff permeates the resists from the above-described exposed surfaces. Therefore, a liftoff time can be shortened, and a liftoff failure can be suppressed.

The metal layer 18 is formed on the mesa 16 in the above-described manner.

As described above, since the metal layer 18 is formed on the mesa 16 without using a resist pattern formed by an exposure machine, dimensional variation of the metal layer 18 can be suppressed. In addition, the metal layer 18 having a dimension less than or equal to a resolution limit of the exposure machine can be formed. When the upper layer resist 22 and the lower layer resist 20 are removed by liftoff, the resists have the exposed surfaces, and the chemical solution easily permeates the resists. This makes it possible to shorten a liftoff time, and to suppress a liftoff failure. Furthermore, the mask used for formation of the mesa 16 and the mask used for formation of the sensitised portion 26 can be shared.

### Embodiment 2

Embodiment 2 is similar to Embodiment 1, but is different from Embodiment 1 in that the upper surface of the lower layer resist is formed flat. A method for manufacturing a semiconductor device according to Embodiment 2 is described with reference to FIGS. 8 to 14.

First, as illustrated in FIG. 8, the mesa 16 is formed on the front surface 14 of the semiconductor substrate 12.

Thereafter, as illustrated in FIG. 9, a lower layer resist 50 having a flat upper surface is formed. The upper surface can be made flat by depositing the lower layer resist 50 thick.

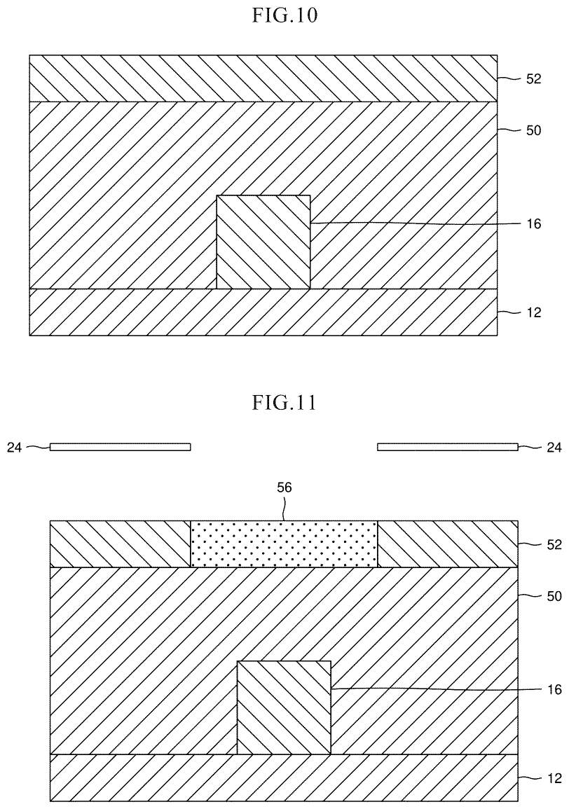

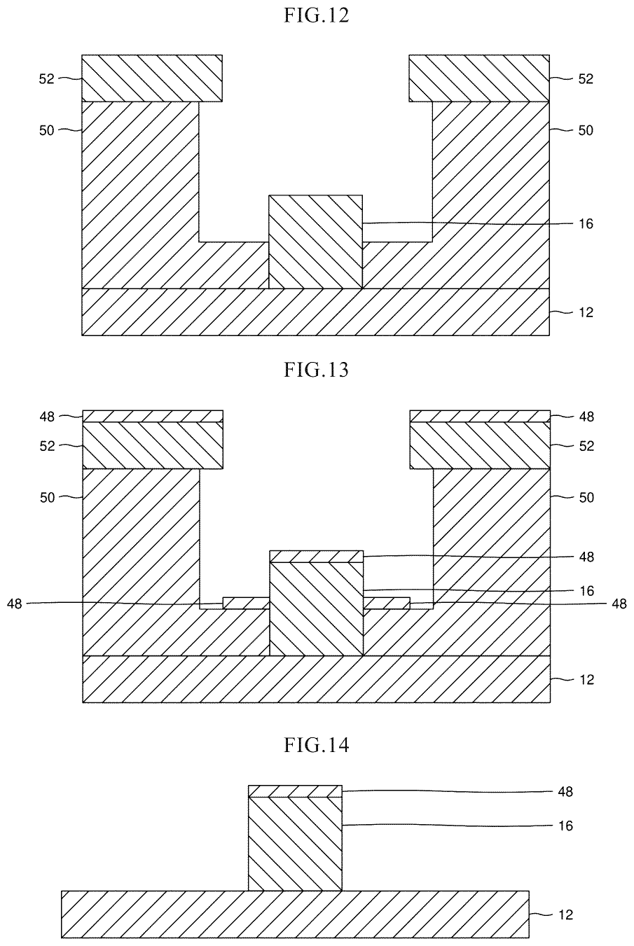

Thereafter, as illustrated in FIG. 10, an upper layer resist 52 is formed. Thereafter, as illustrated in FIG. 11, a sensitised portion 56 is formed. Thereafter, as illustrated in FIG. 12, the sensitised portion 56 and a part of the lower layer resist 50 are removed by a developer.

Thereafter, as illustrated in FIG. 13, a metal layer 48 is formed. Thereafter, as illustrated in FIG. 14, the upper layer resist 52 and the lower layer resist 50 are removed by liftoff. The metal layer 48 is formed on the mesa 16 in the above-described manner.

In Embodiment 2, since the upper surface of the lower layer resist 50 is flat, an area of an exposed surface of the lower layer resist 50 is large after the metal layer 48 is formed as illustrated in FIG. 13. Therefore, when the lower layer resist 50 is removed by liftoff, the chemical solution quickly permeates the lower layer resist 50. This makes it possible to shorten a liftoff time, and to suppress a liftoff failure.

### Embodiment 3

Embodiment 3 is similar to Embodiment 1, but is different from Embodiment 1 in that, after the upper layer resist is formed, etch-back is performed without performing formation of a sensitised portion by using a mask. A method for manufacturing a semiconductor device according to Embodiment 3 is described with reference to FIGS. 15 to 21.

First, as illustrated in FIG. 15, the mesa 16 is formed on the front surface 14 of the semiconductor substrate 12.

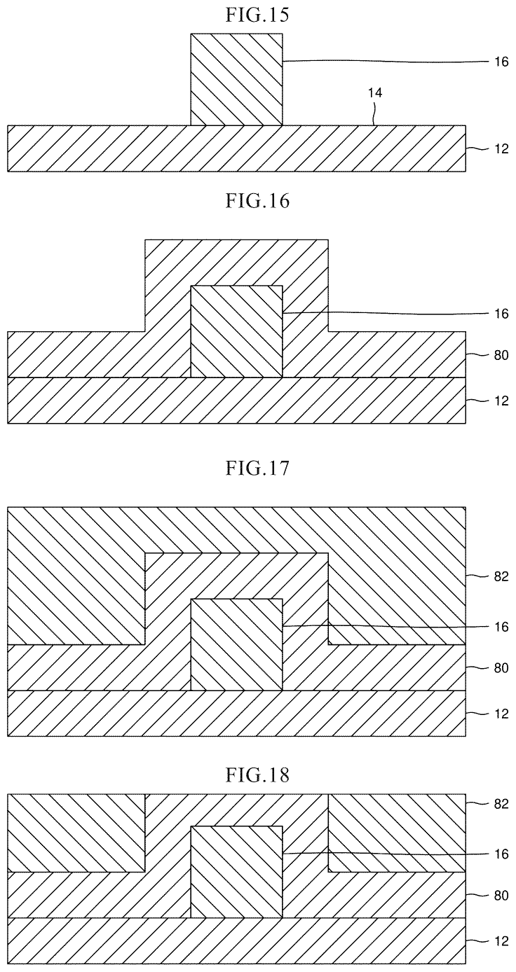

Thereafter, as illustrated in FIG. 16, a lower layer resist 80 is formed. At this time, the lower layer resist 80 is formed such that a portion on the mesa 16 is raised.

Thereafter, as illustrated in FIG. 17, an upper layer resist 82 is formed.

Thereafter, as illustrated in FIG. 18, etch-back of the upper layer resist 82 is performed.

The etch-back is performed until a portion of the lower layer resist 80 covering the mesa 16 is exposed. A part of the lower layer resist 80 may be etched back. The etch-back is performed by, for example, O₂ ashing.

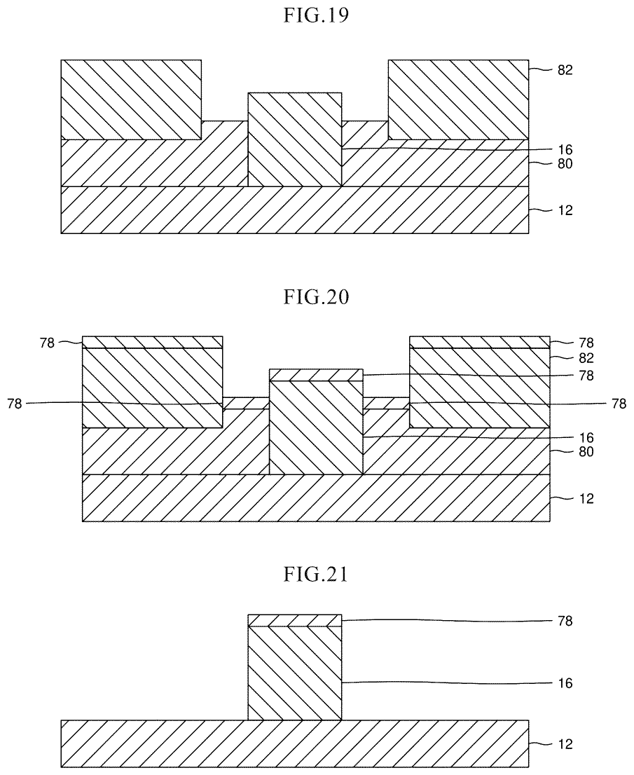

Thereafter, as illustrated in FIG. 19, a part of the lower layer resist 80 is removed by a developer. Thereafter, as illustrated in FIG. 20, a metal layer 78 is formed. Thereafter, as illustrated in FIG. 21, the upper layer resist 82 and the lower layer resist 80 are removed by liftoff. The metal layer 78 is formed on the mesa 16 in the above-described manner.

In Embodiment 3, formation of a sensitised portion by using a mask is not performed. Therefore, the number of steps can be reduced.

### REFERENCE SIGNS LIST

12 semiconductor substrate, 14 front surface, 16 mesa, 18,48,78 metal layer, 20,50,80 lower layer resist, 22,52,82 upper layer resist, 26,56 sensitised portion,

1. A method for manufacturing a semiconductor device, the method comprising:
forming a mesa on a front surface of a semiconductor substrate;
forming a lower layer resist soluble in a developer, to cover the front surface and the mesa;
forming an upper layer resist in which a sensitised region is soluble in a developer, to cover the lower layer resist;
forming a sensitised portion by sensitising a region of the upper layer resist covering at least the mesa in a width direction of the mesa as viewed from a direction perpendicular to the front surface;
exposing an upper surface of the mesa by removing the sensitised portion and a part of the lower layer resist by using a developer;
forming a metal layer on the mesa, on the upper layer resist, and on a region in contact with at least the mesa, of a surface of the lower layer resist exposed when exposing the upper surface of the mesa; and
removing portions of the metal layer on the upper layer resist and the lower layer resist, the upper layer resist, and the lower layer resist.

2. The method for manufacturing the semiconductor device according to claim 1, wherein, when forming the lower layer resist, an upper surface of the lower layer resist is formed flat.

3. The method for manufacturing the semiconductor device according to claim 1, wherein the sensitised portion is smaller than the lower layer resist covering the mesa in the width direction of the mesa as viewed from the direction perpendicular to the front surface.

4. A method for manufacturing a semiconductor device, the method comprising:
forming a mesa on a front surface of a semiconductor substrate;
forming a lower layer resist soluble in a developer, to cover the front surface and the mesa and to be raised on the mesa;
forming an upper layer resist to cover the lower layer resist;
exposing a portion of the lower layer resist covering the mesa by etching back the upper layer resist;
exposing an upper surface of the mesa by removing, by using the developer, a part of the lower layer resist from a portion exposed when exposing the lower layer resist;
forming a metal layer on the mesa, on the upper layer resist, and on the lower layer resist exposed when exposing the upper surface of the mesa; and
removing portions of the metal layer on the upper layer resist and the lower layer resist, the upper layer resist, and the lower layer resist.

5. The method for manufacturing the semiconductor device according to claim 2, wherein the sensitised portion is smaller than the lower layer resist covering the mesa in the width direction of the mesa as viewed from the direction perpendicular to the front surface.
